(19) United States
(12) Patent Application Publication
(10) Pub. No.: US 2025/0273921 A1
(43) Pub. Date: Aug. 28, 2025

(54) INTRACAVITY PUMPING OF LASER GAIN MATERIAL

(71) Applicant: DeUVe Photonics, Inc., Tucson, AZ (US)

(72) Inventors: Chris Hessenius, Tucson, AZ (US); Mahmoud Fallahi, Tucson, AZ (US)

(21) Appl. No.: 19/059,874

(22) Filed: Feb. 21, 2025

Related U.S. Application Data
(60) Provisional application No. 63/557,835, filed on Feb. 26, 2024.
(60) Provisional application No. 63/572,696, filed on Apr. 1, 2024.

(51) Int. Cl. H01S 3/0941; H01S 3/02; H01S 3/108; H01S 3/16; H01S 5/183

(52) U.S. Cl. CPC H01S 3/09415; H01S 3/025; H01S 3/108; H01S 3/1643; H01S 5/183

(57) ABSTRACT

A multi-cavity system for intracavity laser pumping, comprising a first laser cavity. The first laser cavity may comprise a first gain chip, configured to generate a first laser beam, and a first end mirror disposed optically in line with the first gain chip, configured to reflect the first laser beam back to the first gain chip. The first laser cavity may further comprise a second gain chip disposed optically in line with the first gain chip. The first laser beam may be configured to excite the second gain chip. The second gain chip may be configured to generate a second laser beam upon excitation by the first laser beam. The system may further comprise a second laser cavity at least partially intersecting with the first laser cavity. The second laser beam may be configured to be directed through the second laser cavity.

### CROSS-REFERENCE TO RELATED APPLICATIONS

This application is a non-provisional and claims benefits of U.S. Provisional Application No. 63/557,835 filed Feb. 26, 2024 and U.S. Provisional Application No. 63/572,696 filed Apr. 1, 2024, the specifications of which are incorporated herein in their entirety by reference.

### FIELD OF THE INVENTION

The present invention is directed to a multi-cavity system comprising a solid-state crystal disposed in a laser cavity pumped by a laser in a separate cavity.

### BACKGROUND OF THE INVENTION

Thin disk architecture for solid-state crystals is attractive, but the short absorption length of the crystal is a problem. Others have designed elaborate “pumping heads” to increase the pump absorption. These pumping heads comprise hundreds to thousands of mirrors configured to adjust the absorption length to properly excite the solid-state crystals. These pumping heads tend to be bulky and costly to manufacture, making it difficult to implement the thin disk architecture into present laser systems. Thus, there exists a present need for an efficient implementation of thin disk architecture in laser cavity systems.

### BRIEF SUMMARY OF THE INVENTION

It is an objective of the present invention to provide systems that allow for a multi-cavity system comprising a solid-state crystal disposed in a laser cavity pumped by a laser in a separate cavity, as specified in the independent claims. Embodiments of the invention are given in the dependent claims. Embodiments of the present invention can be freely combined with each other if they are not mutually exclusive.

The present invention features a multi-cavity system for intracavity laser pumping, comprising a first laser cavity. The first laser cavity may comprise a first gain chip, configured to generate a first laser beam and a first end mirror disposed optically in line with the first gain chip, configured to reflect the first laser beam back to the first gain chip. The first laser cavity may further comprise a second gain chip disposed optically in line with the first gain chip. The first laser beam may be configured to excite the second gain chip. The second gain chip may be configured to generate a second laser beam upon excitation by the first laser beam. The system may further comprise a second laser cavity at least partially intersecting with the first laser cavity. The second laser beam may be configured to be directed through the second laser cavity.

One of the unique and inventive technical features of the present invention is the implementation of a solid-state gain medium disposed in a first cavity, and pumped by a laser in a second cavity. Without wishing to limit the invention to any theory or mechanism, it is believed that the technical feature of the present invention advantageously provides for the efficient implementation of thin disk architecture in a laser cavity system. None of the presently known prior references or work has the unique inventive technical feature of the present invention.

Furthermore, the inventive technical features of the present invention contributed to a surprising result. One of ordinary skill in the art would not implement a second gain chip within a first laser cavity that is excited by the laser beam(s) within the first cavity because the beam produced by the second gain chip would cause the laser beam(s) to lose power and the power of the laser beam(s) generated by the second gain chip would be proportional to the power lost. The present invention defines limits on the power usage of the second gain chip so that the loss of the first lasers and the power necessities of the second lasers are optimized. Surprisingly, the intracavity system of the present invention is able to accommodate two intersecting laser cavities configured to contain their own lasers for individual applications without losing efficiency in either application. Thus, the inventive technical feature of the present invention contributed to a surprising result.

Any feature or combination of features described herein are included within the scope of the present invention provided that the features included in any such combination are not mutually inconsistent as will be apparent from the context, this specification, and the knowledge of one of ordinary skill in the art. Additional advantages and aspects of the present invention are apparent in the following detailed description and claims.

### BRIEF DESCRIPTION OF THE SEVERAL VIEWS OF THE DRAWING(S)

The features and advantages of the present invention will become apparent from a consideration of the following detailed description presented in connection with the accompanying drawings in which:

FIG. 1 shows the intracavity pumping system of the present invention.

FIG. 2 shows an alternate embodiment of the intracavity pumping system of the present invention, comprising a plurality of second gain chips excited by the first laser beam to generate additional laser beams in a second cavity.

FIG. 3 shows an alternate embodiment of the intracavity pumping system of the present invention, comprising a plurality of gain chips configured to generate laser beams to excite a second gain chip to generate an additional laser beam in a second cavity.

FIG. 4 shows an alternate embodiment of the intracavity pumping system of the present invention, comprising a plurality of first gain chips configured to generate laser beams to excite a plurality of second gain chips to generate additional laser beams in a second cavity.

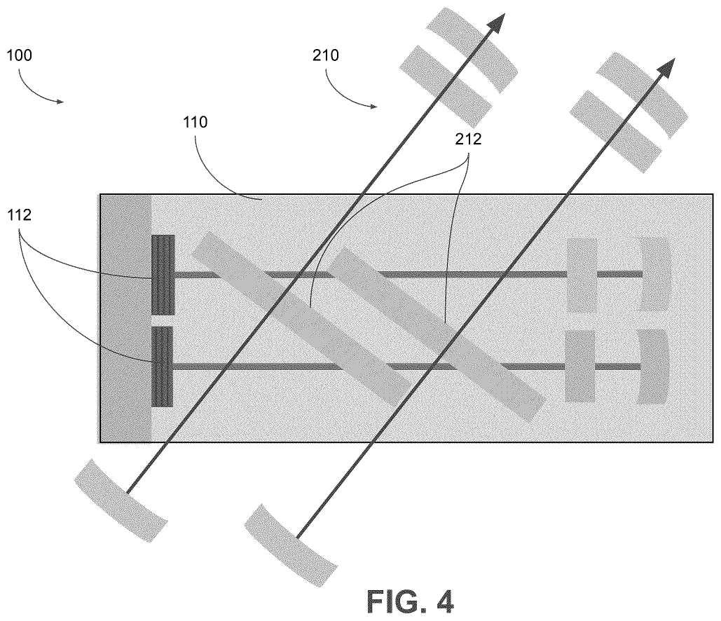

### DETAILED DESCRIPTION OF THE INVENTION

Following is a list of elements corresponding to a particular element referred to herein:
100 system
110 first laser cavity
112 first gain chip
114 first end mirror
116 first set of optical elements
210 second laser cavity
212 second gain chip
214 second end mirror
216 second set of optical elements

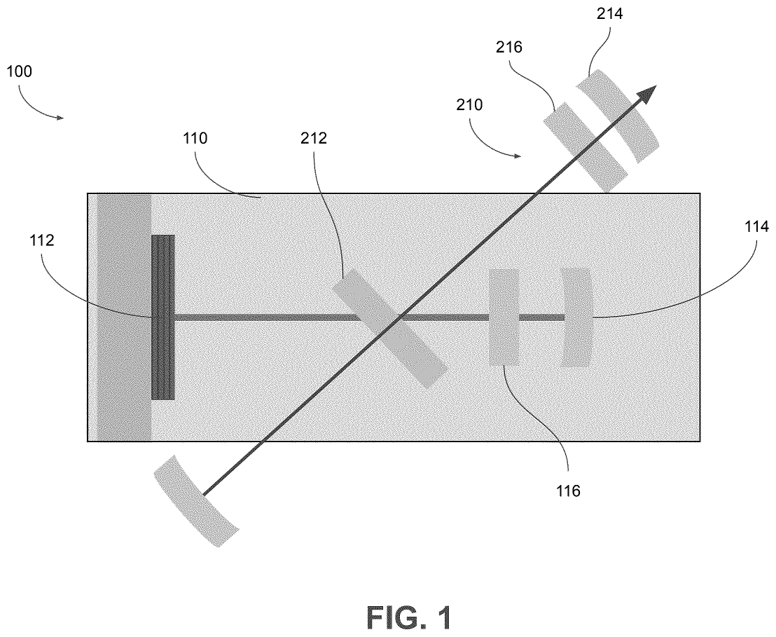

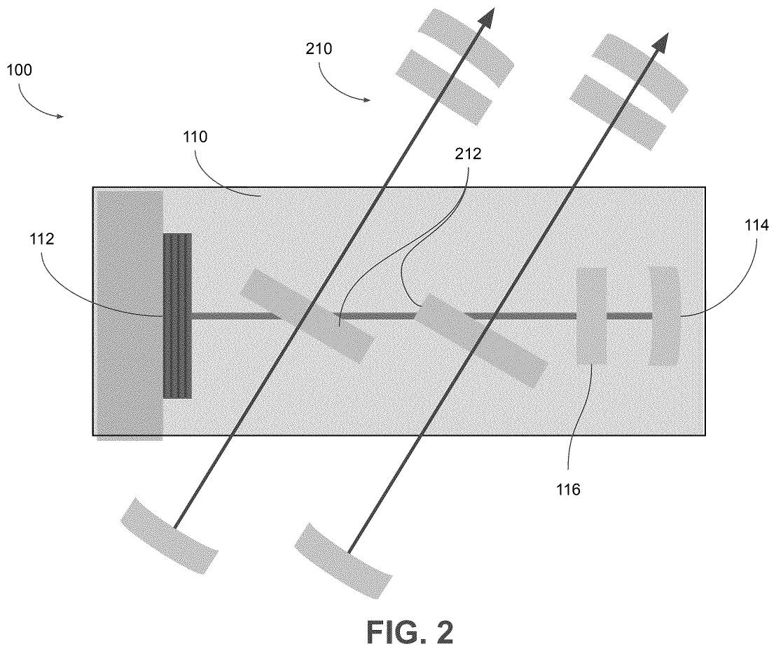

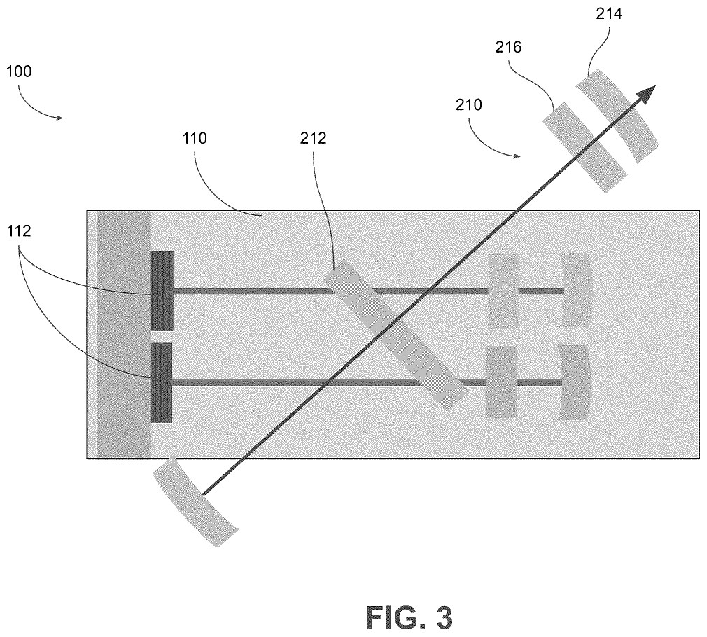

Referring now to FIGS. 1-3, the present invention features a multi-cavity system (100) for intracavity laser pumping. In some embodiments, the system (100) may comprise a first laser cavity (110) comprising one or more first gain chips (112) disposed within the first laser cavity (110), configured to generate one or more first laser beams. The first laser cavity (110) may further comprise one or more second gain chips (212) disposed within the first laser cavity (110) optically in-line with the one or more first gain chips (112). The one or more first laser beams may be configured to excite the one or more second gain chips (212). The one or more second gain chips (212) may be configured to generate one or more second laser beams upon excitation. The system (100) may further comprise a second laser cavity (210) at least partially intersecting with the first laser cavity (110). The one or more second laser beams may be configured to be directed through the second laser cavity (210).

The present invention features a multi-cavity system (100) for intracavity laser pumping. The system (100) may comprise a first laser cavity (110) having a first end and a second end. The first laser cavity (110) may comprise a first gain chip (112) disposed at the first end, configured to generate a first laser beam, and a first end mirror (114) disposed at the second end, optically in line with the first gain chip (112), configured to reflect the first laser beam back to the first gain chip (112). The first laser cavity (110) may further comprise a second gain chip (212) disposed optically in line with the first gain chip (112). The first laser beam may be configured to excite the second gain chip (212). The second gain chip (212) may be configured to generate a second laser beam upon excitation by the first laser beam. The system (100) may further comprise a second laser cavity (210) at least partially intersecting with the first laser cavity (110). The second laser beam may be configured to be directed through the second laser cavity (210).

In some embodiments, the first laser cavity (110) may comprise a vertical external-cavity surface-emitting laser. In some embodiments, the second gain chip (212) may comprise a solid-state crystal. In some embodiments, the solid-state crystal may comprise a ytterbium: yttrium-aluminum-garnet (Yb:YAG) material. In some embodiments, the first laser cavity (110) may further comprise a first set of optical elements (116). The first laser beam may be configured to intersect with the first set of optical elements (116). In some embodiments, the first set of optical elements (116) may comprise one or more frequency-selective elements, one or more electro-optical elements, one or more q-switches, one or more nonlinear optics, or a combination thereof.

In some embodiments, the second laser cavity (210) may comprise an energy source configured to further excite the second gain chip (212). In some embodiments, the second laser cavity (210) may comprise a second end mirror (214) configured to reflect the second laser beam back to the second gain chip (212). In some embodiments, the second laser cavity (210) may comprise a second set of optical elements (216). The second laser beam may be configured to intersect with the second set of optical elements (216). In some embodiments, the second set of optical elements (216) may comprise one or more frequency-selective elements, one or more electro-optical elements, one or more q-switches, one or more nonlinear optics, or a combination thereof. In some embodiments, the first gain chip (112) may be configured to tune the first laser beam to peak absorption in the second gain chip (212).

In some embodiments, the second gain chips (212) may be limited in power usage to optimize the functionality of the first laser beams and the second laser beams. In some embodiments, the second gain chips may be limited in power such that the first laser beams suffer a loss of 5% or less from exciting the second gain chips. In some embodiments, the second gain chips may be limited in power such that the first laser beams suffer a loss of 1 to 10 percent from exciting the second gain chips. In some embodiments, the second gain chips may be limited in power such that the first laser beams suffer a loss of 0.1 to 5 percent from exciting the second gain chips.

In some embodiments, the first laser cavity and the second laser cavity may each have any shape with any number of bends, any number of ends, any number of optical components, any number of gain chips, and any number of laser beams as long as at least one gain chip is shared by both the first laser cavity and the second laser cavity, and the at least one shared gain chip is excited by at least one laser beam produced by at least one gain chip in the first laser cavity such that at least one laser beam is directed through the second laser cavity by the at least one shared gain chip.

Although there has been shown and described the preferred embodiment of the present invention, it will be readily apparent to those skilled in the art that modifications may be made thereto which do not exceed the scope of the appended claims. Therefore, the scope of the invention is only to be limited by the following claims. In some embodiments, the figures presented in this patent application are drawn to scale, including the angles, ratios of dimensions, etc. In some embodiments, the figures are representative only and the claims are not limited by the dimensions of the figures. In some embodiments, descriptions of the inventions described herein using the phrase “comprising” includes embodiments that could be described as “consisting essentially of” or “consisting of”, and as such the written description requirement for claiming one or more embodiments of the present invention using the phrase “consisting essentially of” or “consisting of” is met.

The reference numbers recited in the below claims are solely for ease of examination of this patent application, and are exemplary, and are not intended in any way to limit the scope of the claims to the particular features having the corresponding reference numbers in the drawings.

What is claimed is:

1. A multi-cavity system (100) for intracavity laser pumping, the system (100) comprising:
a. a first laser cavity (110) comprising:
i. one or more first gain chips (112) disposed within the first laser cavity (110), configured to generate one or more first laser beams; and
ii. one or more second gain chips (212) disposed within the first laser cavity (110) optically in-line with the one or more first gain chips (112), wherein the one or more first laser beams are configured to excite the one or more second gain chips (212), wherein the one or more second gain chips (212) are configured to generate one or more second laser beams upon excitation; and
b. a second laser cavity (210) at least partially intersecting with the first laser cavity (110), wherein the one or more second laser beams are configured to be directed through the second laser cavity (210).

2. A multi-cavity system (100) for intracavity laser pumping, the system (100) comprising:
a. a first laser cavity (110) having a first end and a second end, the first laser cavity (110) comprising:
i. a first gain chip (112) disposed at the first end, configured to generate a first laser beam;
ii. a first end mirror (114) disposed at the second end, optically in line with the first gain chip (112), configured to reflect the first laser beam back to the first gain chip (112); and
iii. a second gain chip (212) disposed optically in line with the first gain chip (112), wherein the first laser beam is configured to excite the second gain chip (212), wherein the second gain chip (212) is configured to generate a second laser beam upon excitation by the first laser beam; and
b. a second laser cavity (210) at least partially intersecting with the first laser cavity (110), wherein the second laser beam is configured to be directed through the second laser cavity (210).

3. The system (100) of claim 2, wherein the first laser cavity (110) comprises a vertical external-cavity surface-emitting laser.

4. The system (100) of claim 2, wherein the second gain chip (212) comprises a solid-state crystal.

5. The system (100) of claim 4, wherein the solid-state crystal comprises a ytterbium: yttrium-aluminum-garnet (Yb:YAG) material.

6. The system (100) of claim 2, wherein the first laser cavity (110) further comprises one or more optical elements (116), wherein the first laser beam is configured to intersect with the one or more optical elements (116).

7. The system (100) of claim 6, wherein the one or more optical elements (116) comprise one or more frequency-selective elements, one or more electro-optical elements, one or more q-switches, one or more nonlinear optics, or a combination thereof.

8. The system (100) of claim 2, wherein the second laser cavity (210) comprises an energy source configured to further excite the second gain chip (212).

9. The system (100) of claim 2, wherein the second laser cavity (210) comprises a second end mirror (214) configured to reflect the second laser beam back to the second gain chip (212).

10. The system (100) of claim 2, wherein the second laser cavity (210) comprises one or more optical elements (216), wherein the second laser beam is configured to intersect with the one or more optical elements (216).

11. The system (100) of claim 10, wherein the one or more optical elements (216) comprise one or more frequency-selective elements, one or more electro-optical elements, one or more q-switches, one or more nonlinear optics, or a combination thereof.

12. A multi-cavity system (100) for intracavity laser pumping, the system (100) comprising:
a. a first laser cavity (110) having a first end and a second end, the first laser cavity (110) comprising:
i. a first gain chip (112) disposed at the first end, configured to generate a first laser beam;
ii. a first end mirror (114) disposed at the second end, optically in line with the first gain chip (112), configured to reflect the first laser beam back to the first gain chip (112);
iii. a second gain chip (212) disposed optically in line with the first gain chip (112), wherein the first laser beam is configured to excite the second gain chip (212), wherein the second gain chip (212) is configured to generate a second laser beam upon excitation by the first laser beam; and
iv. a first set of optical elements (116) disposed within the first laser cavity (110), wherein the first laser beam is configured to intersect with the first set of optical elements (116); and
b. a second laser cavity (210) at least partially intersecting with the first laser cavity (110), wherein the second laser beam is configured to be directed through the second laser cavity (210), the second laser cavity (210) comprising:
i. a second end mirror (214) disposed within the second laser cavity (210), optically in line with the second gain chip (212), configured to reflect the second laser beam back to the second gain chip (212); and
ii. a second set of optical elements (216) disposed within the second laser cavity (210), wherein the second laser beam is configured to intersect with the second set of optical elements (216).

13. The system (100) of claim 12, wherein the first laser cavity (110) comprises a vertical external-cavity surface-emitting laser.

14. The system (100) of claim 12, wherein the second gain chip (212) comprises a solid-state crystal.

15. The system (100) of claim 14, wherein the solid-state crystal comprises a ytterbium: yttrium-aluminum-garnet (Yb:YAG) material.

16. The system (100) of claim 12, wherein the first set of optical elements (116) comprises one or more frequency-selective elements, one or more electro-optical elements, one or more q-switches, one or more nonlinear optics, or a combination thereof.

17. The system (100) of claim 12, wherein the second laser cavity (210) further comprises an energy source configured to further excite the second gain chip (212).

18. The system (100) of claim 12, wherein the second set of optical elements (216) comprises one or more frequency-selective elements, one or more electro-optical elements, one or more q-switches, one or more nonlinear optics, or a combination thereof.
